(19) United States
(12) Patent Application Publication
(10) Pub. No.: US 2026/0074142 A1
(43) Pub. Date: Mar. 12, 2026

(54) ELECTRON BEAM MICROSCOPE

(71) Applicant: Carl Zeiss Microscopy GmbH, Jena (DE)

(72) Inventor: Erik ESSERS, Aalen (DE)

(21) Appl. No.: 19/322,773

(22) Filed: Sep. 9, 2025

(30) Foreign Application Priority Data
Sep. 10, 2024 (DE) 10 2024 002 912.5

(51) Int. Cl. H01J 37/244; H01J 37/10; H01J 37/20

(52) U.S. Cl. CPC H01J 37/244; H01J 37/10; H01J 37/20; H01J 2237/2443

(57) ABSTRACT

An electron beam microscope comprises an electron beam source, an objective lens and an electron detector. The electron detector comprises a scintillator arrangement between the electron beam source and an object location so that electrons generated at the object are incident on a scintillator body that is formed from a scintillator material that generates light from incident electrons. The electron detector also comprises a light detector for detecting the light generated by the scintillator body and an optical element comprising an optically effective surface between the scintillator arrangement and the object location and arranged between the scintillator body and the light detector in a beam path of the light detected by the light detector.

### CROSS-REFERENCE TO RELATED APPLICATION

This application claims benefit under 35 U.S. C. § 119 to German Application No. 10 2024 002 912.5, filed Sep. 10, 2024. The entire disclosure of this application is incorporated by reference herein.

### FIELD

The disclosure relates to an electron beam microscope that comprises an electron detector.

### BACKGROUND

A conventional electron beam microscope comprises an electron beam source for generating an electron beam, an object holder for mounting an object to be examined using the electron beam microscope, an objective lens for focusing the electron beam onto the object and an electron detector for detecting electrons generated at the object by the electron beam.

The electron detector comprises a converter that on account of incident electrons directly generates electrical signals or light, and the light is detected in turn in order to generate electrical signals. On account of the configuration of the electron detector in respect of e.g. geometric extent and the desire for additional components, such as light guides and electrical lines, the use of the electron detector is subject to boundary conditions that sometimes prevent electrons from being able to be detected at desired positions within the electron beam microscope.

### SUMMARY

It is desirable to obtain further configurations of electron detectors that extend the area of use of the electron detectors.

According to the disclosure, an electron beam microscope comprises an electron beam source for generating an electron beam, an object holder for mounting an object at an object location on which the electron beam is incident, an objective lens arranged along a beam path of the electron beam between the electron source and the object location and serving to focus the electron beam on the object location and a first electron detector for detecting electrons generated at the object.

According to embodiments, the first electron detector comprises a scintillator arrangement that is arranged in such a way along the beam path of the electron beam between the electron beam source and the object location that the electrons generated at the object are incident on the scintillator body. The scintillator arrangement comprises a scintillator body which is formed from a scintillator material that generates light using incident electrons. The first electron detector also comprises a light detector for detecting light generated by the scintillator body or the scintillator arrangement and for converting the light into electrical signals. The first electron detector also comprises an optical element comprising an optically effective surface that is arranged in such a way along the beam path of the electron beam between the scintillator arrangement and the object location that the optically effective surface is arranged closer to the object location than the scintillator arrangement. The optically effective surface is arranged between the scintillator arrangement and the light detector in a beam path of the light detected by the light detector. Thus, so that the light generated by the scintillator body can reach the light detector, at least some of the light initially reaches the optically effective surface. Since the optically effective surface is arranged closer to the object location than the scintillator body, the light generated by the scintillator body is directed towards the optically effective surface and hence towards the plane that intersects the beam path of the electron beam orthogonally at the object.

The beam path between the scintillator arrangement and the optically effective surface is at least partially in vacuo. The beam path between the optically effective surface and the light detector is also at least partially in vacuo. The distance between the scintillator arrangement and the optically effective surface measured along the beam path between the optically effective surface and the light detector is for example 2 mm, 4 mm or more. The distance between the optically effective surface and the light detector measured along the beam path in vacuo between the optically effective surface and the light detector is for example 2 mm, 4 mm or more. In addition to the scintillator body, the scintillator arrangement may comprise a light guiding body such that light generated by the scintillator body either directly exits the scintillator arrangement in order to be detected or initially enters the light guiding body before it exits the latter and the scintillator arrangement in order to be detected. The light guiding body may act as a carrier for the scintillator body should the scintillator body have a particularly thin embodiment or be applied to the light guiding body as a coating. Some or all of the scintillator arrangement may be coated with an electrically conductive layer that avoids local electrical charging of the surface of the scintillator arrangement. According to exemplary embodiments, the mirror surface is a curved surface. According to exemplary embodiments herein, there exists an ellipsoid as a mathematical surface such that the mirror surface is fitted to parts of the ellipsoid, and a greatest distance between the mirror surface and the ellipsoid can be less than 5 mm or is less than 3 mm. The ellipsoid as a mathematical surface arises by way of a rotation of an ellipse about its major axis. In this case, the distance between the scintillator body and a focus of the ellipsoid can be less than 3 mm.

According to exemplary embodiments, there exists a paraboloid as a mathematical surface such that the mirror surface is fitted to parts of the paraboloid, and a greatest distance of the effective mirror surface from the paraboloid is less than 3 mm. The paraboloid as a mathematical surface arises by way of a rotation of the parabola about its axis of symmetry.

According to exemplary embodiments, the optical element is a lens, and the optically effective surface is a lens surface at which the light detected by the light detector experiences light refraction. In this case, the lens surface may be formed by an electrically conductive layer that is transmissive to the light generated by the scintillator body. Furthermore, the lens may have an optical axis which is inclined relative to the beam path of the electron beam and which makes a smallest angle of greater than 4°, such as greater than 10°, with the beam path.

According to exemplary embodiments, the optically effective surface is greater than 10 mm², such as greater than 100 mm².

According to further exemplary embodiments, the optical element comprises a cutout through which the beam path of the electron beam extends such that, firstly, the electron beam from the electron beam source to the object is able to pass through the optical element and, secondly, the electrons generated at the object are able to pass through the optical element to the scintillator arrangement.

According to exemplary embodiments, the first electron detector comprises a light guide arranged between the optically effective surface and the light detector in the beam path of the light detected by the light detector.

According to exemplary embodiments, the scintillator arrangement comprises an electron reception surface on which the electrons generated at the object are incident on the scintillator body. Further, the scintillator arrangement comprises a light exit surface through which the light generated by the scintillator material exits the scintillator arrangement. In this case, it is possible for there to be an at least partial overlap between the electron reception surface and the light exit surface.

According to exemplary embodiments, the electron beam microscope comprises a further, second electron detector that is configured to detect electrons generated at the object by the electron beam, the generated electrons having a kinetic energy that is greater than an adjustable limit value. This secondary electron detector comprises a converter that is configured to convert the electrons generated at the object and incident on the converter into electrical or optical signals. The second electron detector also comprises a first electrode, a second electrode, a tube and an insulator. The beam path of the electron beam directed at the object passes through the tube in the longitudinal direction of the latter. The tube is electrically conductive and serves to shield the electron beam passing through the tube from electric fields that are generated outside of the tube by the first and the second electrode. The converter, the first electrode and the second electrode respectively extend in planes oriented orthogonally to the beam path of the electron beam. The first electrode, the second electrode and the converter are arranged in this order and at a distance from each other. Electrons generated at the object by the electron beam and incident on the converter pass through first the first electrode and then the second electrode before they are incident on the converter. The first and the second electrode may be formed from electrically conductive grids or meshes. An adjustable electric potential that defines the threshold value for the kinetic energy of the electrons which can be converted by the converter into optical or electrical signals can be applied to the second electrode by a controller of the electron beam microscope. The electric potentials of the first electrode and of the converter may be the same, may be jointly adjustable or may be adjustable independently of each other. For example, the electric potentials of the first electrode and of the converter may be the same as the electric potential of the tube that is traversed by the electron beam. The insulator surrounds the tube along the beam path of the electron beam, at least between the first electrode and the second electrode and between the second electrode and the converter, and is provided to prevent the uniform electric fields that arise between the first electrode and the second electrode and between the second electrode and the converter from being adversely affected and deformed by the electric potential of the tube that is traversed by the electron beam.

According to exemplary embodiments, the scintillator arrangement of the first electron detector is arranged along the beam path of the electron beam between the first electrode and the object location or between the second electrode and the object location. As seen from the object location and in the direction of the beam path, the converter and the insulator may overlap. As seen from the object location and in the direction of the beam path, the converter may in this case be arranged outside of the tube or overlap with the tube. Hence, the first electron detector is able to detect electrons that would not be detectable without the presence of the converter of the first electron detector upstream of the insulator or upstream of the tube. Without the presence of the converter of the first electron detector, the cross-sectional area of the insulator forms a dead area, on which electrons generated at the object by the electron beam and carrying information regarding the properties of the object at the object location are incident but not detectable. By way of the scintillator body of the first electron detector arranged upstream of the insulator, these electrons are detectable by the first electron detector.

According to exemplary embodiments, an electron beam microscope comprises an electron beam source for generating an electron beam, an object holder for mounting an object at an object location on which the electron beam is incident, an objective lens for focusing the electron beam on the object location, a first electron detector for detecting electrons generated at the object by the electron beam and the above-described second electron detector.

The first electron detector can comprise a converter configured to convert electrons generated at the object into electrical or optical signals, wherein, from the view of the object, this converter is arranged in front of the insulator of the second electron detector.

According to exemplary embodiments, the converter of the first electron detector is formed by a semiconductor detector that generates electrical signals as a result of the electrons generated at the object and incident on the converter.

According to exemplary embodiments, the electron beam microscope also comprises a beam tube which has an electrically conductive inner lateral surface and into which the electron beam enters at a first end of the beam tube and from which the electron beam exits at a second end of the beam tube. The converter of the first electron detector is arranged between the first end and the second end of the beam tube and arranged within the beam tube. The converter of the second electron detector may also be arranged within the beam tube between the first end and the second end of the beam tube.

According to exemplary embodiments, the objective lens provides a focusing magnetic field for focusing the electron beam. The focusing magnetic field has a maximum. This maximum may be arranged along the beam path of the electron beam between the first end and the second end of the beam tube. Further, the converter of the first electron detector may be arranged along the beam path of the electron beam between the electron beam source and the maximum.

According to exemplary embodiments, an electron microscope comprising an electron beam source for generating an electron beam, an object holder for mounting an object at an object location on which the electron beam is incident, an objective lens for focusing the electron beam on the object, a first electron detector for detecting electrons generated at the object and a second electron detector for detecting electrons generated at the object may be configured such that the second electron detector comprises a converter configured to convert electrons generated at the object and incident on an electron reception surface of the converter into electrical or optical signals.

The first electron detector may comprise a converter that is configured to convert electrons generated at the object and incident on an electron reception surface of the converter into light. In this case, the converter of the first electron detector may comprise a scintillator body that provides the electron reception surface of the converter and is formed from a scintillator material which generates the light from electrons generated at the object and incident on the scintillator body.

In this case, the following observation can be made regarding a plane that intersects the scintillator body of the first electron detector and is orthogonal to a beam path of the electron beam in the vicinity of the scintillator body: this plane includes a location at which the electron beam passes through the plane during operation. The scintillator body at least partially surrounds this location. Hence, this location may be considered to be a centre, around which the scintillator body is arranged. For example, the scintillator body has the form of an annulus in this plane, i.e. the form of a circular plate with a central hole. In this case, it is not necessary for the scintillator body to have an exactly annular form. The scintillator body may also have a form that has an edge that is close to the centre and for example has a polygonal form. Likewise, the scintillator body may have an edge that is at a distance from the centre and for example has a polygonal form.

Furthermore, the scintillator body need not extend entirely and without interruptions around the centre. Instead, it is possible that provision is made for a scintillator body that extends around the centre over only a portion of the circumference. Further, a plurality of scintillator bodies might be provided, each of which extends around the centre over only portions of the circumference and together are arranged adjacent to one another in the circumferential direction around the centre.

In the plane under consideration, there is a region traversed by electrons that are generated at the object by the electron beam and incident on the electron reception surface of the second electron detector. In relation to the centre, this region is situated outside of the scintillator body of the first electron detector, or - expressed differently - the scintillator body is arranged between the centre and those locations on the plane at which the electrons detected by the second electron detector pass through the plane. Expressed differently yet again, the scintillator body is intersected by a straight connecting line that connects the centre and a respective location in the plane at which the electron detected by the second electron detector passes through the plane.

According to exemplary embodiments, the first electron detector comprises a light guide and a light detector. The scintillator arrangement comprises a light exit surface through which the light generated by the scintillator material can exit the scintillator arrangement. The light guide comprises a light entrance surface through which the light exiting through the light exit surface of the scintillator arrangement can enter the light guide. The light guide is configured to guide the light entering the light guide through the light entrance surface to the light detector.

According to exemplary embodiments, the following observation can also be made within the plane that passes through the scintillator body and is orthogonal to the beam path: there exist electrons generated at the object and detected by the second electron detector that pass through the plane in a portion that is arranged between the light exit surface of the scintillator arrangement and the light entrance surface of the light guide. In other words, this means that a volume region arranged between the light exit surface and the light entrance surface is firstly traversed by the light generated by the scintillator arrangement of the first electron detector and detected by the light detector of the first electron detector and secondly traversed by the electrons generated at the object and detected by the second electron detector.

According to exemplary embodiments, the light exit surface of the scintillator arrangement is provided with an electrically conductive and light-transmissive layer. According to further exemplary embodiments, surfaces of the scintillator arrangement that differ from the light exit surface are provided at least in part, i.e. in part or in full, with a light-reflective layer, which is electrically conductive for example. The coatings of the scintillator arrangement have an electrically conductive configuration in order to prevent local electrical charging from occurring on the surface at locations at which electrons might be incident during the operation of the electron beam microscope as the electrical charging may lead to electrical flashovers or may inadvertently influence trajectories of the electron beam or of the electrons to be detected.

Parts of the surface of the scintillator arrangement that are not part of the light exit surface of the scintillator arrangement can be provided with light-reflective coatings in order to prevent light situated within the scintillator arrangement from being able to depart the scintillator arrangement in a direction at which it would not be incident on the light entrance surface of the light guide. As a result of the reflective coating, such light is reflected one or more times within the scintillator arrangement in order to be provided with the opportunity to be incident on the light exit surface, which is light-transmissive, and so the light can be incident on the light entrance surface of the light guide and ultimately be detected by the light detector.

As seen in the plane that intersects the scintillator body and is orthogonal to the beam path of the electron beam, the light entrance surface has a concave embodiment according to exemplary embodiments. This reduces the component of the light reflected off the light entrance surface and by way of light refraction changes the direction of the light, which enters the light guide through the light entrance surface, towards the light detector.

According to exemplary embodiments, the following observation may arise in the plane that intersects the scintillator body of the first electron detector and is orthogonal to the beam path of the electron beam: the light entrance surface of the light guide extends completely around the centre, and/or the light entrance surface of the light guide completely surrounds the scintillator body. If the scintillator body itself completely surrounds the centre, a region of the plane in which the locations at which the electrons generated at the object and detected by the second electron detector pass through the plane is located between the scintillator body and the light entrance surface of the light guide. Hence, in this plane, the scintillator body of the first electron detector is completely surrounded by the region in which the electrons detected by the second electron detector pass through the plane.

Embodiments of the disclosure are explained in detail below with reference to the drawings.

### BRIEF DESCRIPTION OF THE DRAWINGS

FIG. 1 is a schematic cross-sectional view of an electron beam microscope according to an embodiment.

FIG. 2 is a schematic cross-sectional view of a portion of an electron beam microscope according to a second embodiment.

FIG. 3 is a schematic cross-sectional view of a portion of an electron beam microscope according to a third embodiment.

FIG. 4 is a schematic cross-sectional view of a portion of an electron beam microscope according to a fourth embodiment.

FIG. 5 is a schematic cross-sectional view of a portion of an electron beam microscope according to a fifth embodiment.

FIG. 6 is a schematic cross-sectional view of a portion of an electron beam microscope according to a sixth embodiment.

FIG. 7 is a cross-sectional view of a portion of the electron beam microscope shown in FIG. 4, along a line VII-VII in FIG. 6.

FIG. 8 is a schematic cross-sectional view of a portion of an electron beam microscope according to a seventh embodiment.

FIG. 9 is a schematic cross-sectional view of a portion of an electron beam microscope according to an eighth embodiment.

FIG. 10 is a schematic cross-sectional view of a portion of an electron beam microscope according to a ninth embodiment.

### DETAILED DESCRIPTION

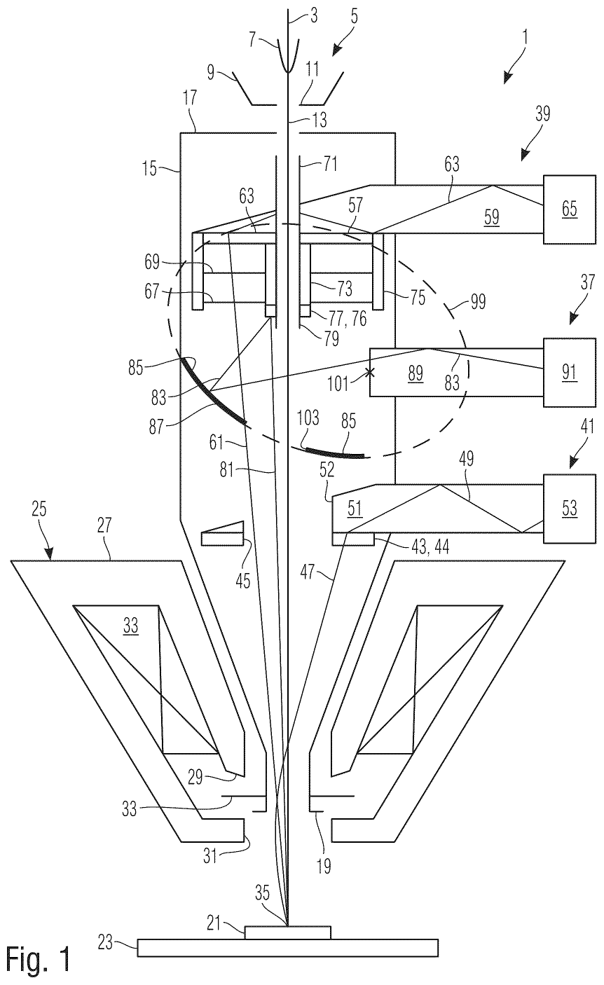

FIG. 1 schematically shows a longitudinal section of an electron beam microscope 1 along a main axis 3 of the electron beam microscope 1. The electron beam microscope 1 comprises an electron beam source 5 having an electron emitter 7 and an extractor electrode 9. The application of a voltage between the electron emitter 7 and the extractor electrode 9 generates such a strong electric field at the tip of the electron emitter 7 that electrons are extracted from the electron emitter 7, accelerated towards the extractor electrode 9 and partly pass through an opening 11 in the extractor electrode 9 in order to generate an electron beam 13, the beam path of which is located on the main axis 3. Hence, FIG. 1 shows the electron beam microscope 1 as seen from a direction perpendicular to a beam path of the electron beam microscope 1.

The electrons in the electron beam 13 enter a beam tube 15 at a first end 17 of the beam tube 15 and pass through the beam tube 15 in the longitudinal direction thereof until they exit the beam tube 15 at a second end 19 thereof in order to be incident on an object 21 that is mounted on an object holder 23 of the electron beam microscope 1.

The electron beam microscope 1 also comprises an objective lens 25 for generating a magnetic field that focuses the electron beam 13 on a surface of the object 21. To this end, the objective lens 25 comprises a magnetic yoke 27 with a first pole end 29 and a second pole end 31, which have a rotationally symmetric design with respect to the main axis 3. Within the magnetic yoke 27, provision is made for a solenoid 33 through which an electric current flows in order to generate a magnetic field that emerges from the magnetic yoke 27 into a gap between the pole ends 29 and 31 at the pole ends 29 and 31. The magnetic field emerging from the pole ends 29, 31 has a focusing effect on the electron beam 13 and has a maximum in a plane 33 that is oriented orthogonal to the main axis 3.

The beam tube 15 is an electrode that surrounds the electron beam 13 between the first end 17 and the second end 19 of the beam tube 15, the electrode being at the same or a greater electric potential than the extractor electrode 9 such that the electrons in the electron beam 13 quickly pass through the beam tube 15 at a high speed. In comparison with the beam tube 15, the object 21 and the object holder 23 are at a lower electric potential, and so the electrons in the electron beam 13 are retarded in an electric field between the second end 19 of the beam tube 15 and the surface of the object 21 in order to be incident on the object with a desired kinetic energy. This kinetic energy is defined by the potential difference between the electron emitter 7 and the object 21. For example, this potential difference may be 4 kV to 15 kV.

The electrons in the electron beam 13 incident on the object 21 at an object location 35 in turn generate electrons that exit the object 21 and are accelerated towards the beam tube 15 in the electric field between the second end 19 of the beam tube 15 and the surface of the object 21. Some of these electrons enter the beam tube at the second end 19 of the beam tube 15. The electrons entering the beam tube 15 move upwardly in the illustration of FIG. 1 and can be detected by a first electron detector 37, a second electron detector 39 and a third electron detector 41.

The electrons generated at the object 21 by the incident electron beam 13 differ in terms of the kinetic energy with which they exit the object 21 and in terms of the direction in which they move upon their exit from the object 21. On account of these differences, diverse electrons exiting from the object 21 can be detected by the various electron detectors 37, 39 and 41.

The electrons exiting the object 21 are usually divided into two groups. The electrons of the one group are referred to as secondary electrons, wherein the kinetic energy of these electrons during the exit from the object 21 is less than 50 electron volts. The electrons of the other group are referred to as backscattered electrons, wherein the kinetic energy of these electrons is greater than 50 electron volts and less than the kinetic energy or equal to the kinetic energy with which the electrons in the electron beam 13 are incident on the object 21.

On account of their lower energy in comparison with the backscattered electrons, many secondary electrons are deflected in quite pronounced fashion when passing through the electric field between the second end 19 of the beam tube 15 and the surface of the object 21 and may be incident on a converter 43 of the third electron detector 41. The converter 43 comprises a scintillator body 44 that extends around the main axis 3 and has a central opening 45, through which the electrons in the electron beam 13 on their path to the object 21 are able to pass through the scintillator body 44 and through which the electrons generated at the object 21 are able to pass through the scintillator body 44 on their path to their detection by the first electron detector 37 and the second electron detector 39. The scintillator body 44 is made of a scintillator material that generates light from electrons incident on the scintillator body 44. In FIG. 1, reference sign 47 is used to denote an exemplary trajectory of an electron that is generated at the object 21 and incident on the scintillator body 43. This electron generates light in the scintillator body 43, the exemplary trajectory of the light being denoted by reference sign 49 in FIG. 1. From the scintillator body 43, the light enters a light guide 51 that is optically coupled to the scintillator body 43 and guides the light to a light detector 53, which detects the light and outputs electrical signals corresponding to the detected light. The light guide 51 has an opening 52 that is flush with the opening 45 of the scintillator body 44 and serves the passage of the electrons.

As a converter, the second electron detector 39 comprises a scintillator body 57 that is optically coupled to a light guide 59. In FIG. 1, reference sign 61 is used to denote an exemplary trajectory of an electron that is generated by the object 21 and incident on the scintillator body 57. This electron generates light in the scintillator body 57, wherein reference sign 63 denotes an exemplary trajectory of such light that is guided by the light guide 59 to a light detector 65, which detects the light and converts the light into corresponding electrical signals.

The electrons incident on the scintillator body 57 initially pass through a first electrode 67 and subsequently pass through a second electrode 69 before they reach the scintillator body 57. The first electrode 67 and the scintillator body 57 are at the same electric potential as the beam tube 15. The electric potential of the second electrode 69 is adjustable and lower than the electric potential of the first electrode 67 such that the second electrode 69 can only be passed by electrons whose kinetic energy is sufficiently high and whose direction of flight and trajectory is appropriately aligned with respect to the grid or mesh. Thus, the electrons that reach the scintillator body 57 can be selected in terms of their kinetic energy by changing the potential of the second electrode 69 and determining the intensity of the light detected by the light detector 65. The first electrode 67 and the second electrode 69 may be formed from a conductive mesh or grid.

In order to shield the electron beam 13 from the influence of the electric fields generated between the first electrode 67 and the second electrode 69 and between the second electrode 69 and the scintillator body 57, provision is made for an electrically conductive tube 71, which passes through the two electrodes 67 and 69, the converter 57 and the light guide 59 in a manner centred with the main axis 3. The tube 71 is at the same electric potential as the beam tube 15.

So that the electric potential of the tube 71 does not influence the electric fields between the two electrodes 67 and 69 and between the second electrode 69 and the converter 57, provision is made for an insulator 73, which surrounds the tube 71 in the region between the first electrode 67 and the converter 57. Furthermore, a further insulator 75 is provided to this end; it surrounds the first electrode 67, the second electrode 69 and the converter 57 on the outside. However, at least at their surface facing the ring-shaped space between the insulators 73 and 75, the insulators 73 and 75 have a certain amount of electrical conductivity so that the electric potential on the outer surface of the insulators 73 and 75 can change uniformly in the longitudinal direction thereof, and the electric fields between the electrodes 67 and 69 and between the electrode 69 and the scintillator body 57 are as homogeneous as possible.

In comparison with the third electron detector 41, the second electron detector 39 detects backscattered electrons to a greater extent since these are deflected less when passing through the objective lens 25. Moreover, the spectrum of kinetic energies of these electrons can be influenced in such a way by changing the electric potential of the second electrode that substantially only backscattered electrons are detected.

The scintillator body 57 may be bombarded by electrons that come from the object 21 and have a distance from the main axis 3 when passing through the first electrode 67 that is greater than the outer radius of the insulator 73. The first electron detector 37 is provided so as to be able to also detect electrons that have a distance from the main axis 3 in the region of the first electrode 67 that is less than the radius of the insulator 73. The first electron detector comprises a scintillator arrangement 76 that is provided at an end face of the insulator 73 facing the object 21 and comprises a scintillator body 77. The scintillator body 77 has the form of a ring cylinder, wherein a central bore of the scintillator body 77 is passed by the tube 71 such that an end 79 of the tube 71 that faces the object 21 is arranged closer to the object location 35 than a surface of the scintillator body 77 that faces the object location 35. An outer diameter of the scintillator body 77 is the same as or slightly larger than the outer diameter of the insulator 73.

In an alternative, it is also possible to arrange the scintillator arrangement 76 between the end 79 of the tube 71 facing the object 21 and the object location 35. In that case, the inner diameter of the scintillator body 77 may be set smaller than the outer diameter of the tube 71, and so electrons that would otherwise be incident on the end face of the tube 71 are incident on the scintillator arrangement 76 of the first electron detector 37 and can be detected.

In FIG. 1, reference sign 81 denotes a trajectory of an electron that is generated at the object location 35 and incident on the scintillator arrangement 76. This electron generates light in the scintillator body 77 of the scintillator arrangement 76, and the light exits the scintillator arrangement 76 into the vacuum. In FIG. 1, reference sign 83 denotes an exemplary trajectory of such light. The light is incident on the mirror surface 85 of a mirror 87, is reflected off the latter and enters a light guide 89 of the first electron detector 37, in order to guide the light to a light detector 91 that detects the light and converts it into electrical signals. The light detector 91 may be arranged outside a vacuum shell, which is not depicted in FIG. 1 and which includes the vacuum chamber in which the beam path of the electron beam 13 is situated. The mirror surface 85 is an optically effective surface that is arranged in the beam path of the light between the scintillator body 77 and the light detector 91.

The mirror surface 85 has a curved form. In FIG. 1, a dashed line 99 denotes an ellipsoid that as a mathematical surface arises from a rotation of an ellipse about its semimajor axis. The mirror surface 85 approximates the form of the ellipsoid 99. For example, the distance between the mirror surface 85 and the ellipsoid 99 at the effective mirror surface 85 is less than 3 mm or less than 1 mm. The ellipsoid 99 is arranged in such a way that the scintillator body 77 is arranged close to the first focus of the ellipse that generates the ellipsoid 99. In that case, a light entrance surface 101 of the light guide 89 is arranged close to the second focus of this ellipse. In this way, the greatest possible component of the light generated by the scintillator body 77 is input coupled into the light guide 89. The mirror 87 has a cutout 103 to allow the electron beam 13 to pass through to the object 21 and to allow the electrons coming from the object 21 to pass through to the converter 57 of the second electron detector 39 and to the scintillator arrangement 76 of the first electron detector. The light entrance surface 101 is approximately at the same electric potential as the beam tube 15.

As seen along the beam path of the electron beam 13, the objective lens 25 is arranged between the electron beam source 5 and the object location 35. Since the beam path of the electron beam 13 in the example shown in FIG. 1 is a straight line and extends vertically, the objective lens 25 is arranged higher than the object location 35 and the electron beam source 5 is arranged higher than the objective lens 25. Furthermore, the scintillator arrangement 76 is arranged along the beam path between the electron beam source 5 and the object location 35, and, in the situation of FIG. 1, this means that the scintillator arrangement 76 is arranged higher than the object location 35 and the electron beam source 5 is arranged higher than the scintillator arrangement 76. Furthermore, the mirror surface 85 is arranged along the beam path of the electron beam 13 between the scintillator arrangement 76 and the object location 35, and, in the situation of FIG. 1, this means that the mirror surface 85 is arranged higher than the object location 35 and the scintillator arrangement 76 is arranged higher than the mirror surface 85.

In the depicted embodiment, the optically effective surface, i.e. the mirror surface 85, is a connected continuous surface. However, it is also possible to design the optically effective surface in such a way that it is composed of a plurality of respective continuous portions, with steps at which portions adjoin each other discontinuously being provided between adjacent portions. It is also possible that the plurality of portions are parts of a plurality of ellipsoids, the associated ellipses of which have different dimensions of their semiaxes, with in each case one focus being arranged close to the scintillator body 77 and the other focus being arranged close to the light entrance surface 101.

Further embodiments of the electron beam microscope are shown below with reference to the figures. In this case, components that correspond in terms of their structure or function to components of the embodiment explained on the basis of FIG. 1 are provided with the same reference sign, albeit with an additional letter to allow a distinction to be made. To understand the structure and the function of these components, reference should be made to the entire preceding description.

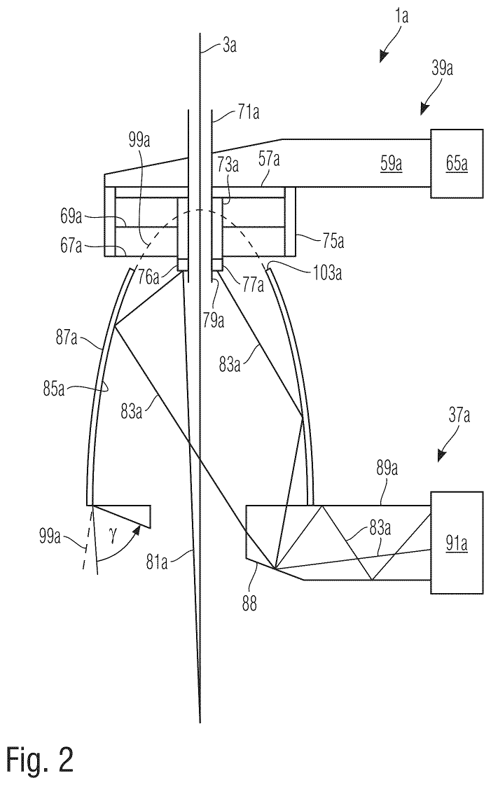

FIG. 2 is a schematic cross-sectional view of a portion of an electron beam microscope according to a second embodiment. The electron beam microscope 1a shown in FIG. 2 merely differs from the electron beam microscope 1 explained on the basis of FIG. 1 in terms of the design of a first electron detector 37a. Thus, the remaining components of the electron beam microscope 1a are substantially the same as the electron beam microscope shown in FIG. 1 and are not repeated below in order to avoid repetition. Further, FIG. 2 only depicts certain components of the electron beam microscope 1a for the explanations in relation to the first electron detector 37a, and the remaining components of the electron beam microscope 1a are not depicted in FIG. 2.

Once again, the electron beam microscope 1a comprises a first electron detector 37a and a second electron detector 39a. The second electron detector 39a of the electron beam microscope 1a has a structure that is the same as the structure of the second electron detector 39 of the electron beam microscope 1 shown in FIG. 1. The second electron detector 39a comprises a tube 71a, which is centred with respect to a main axis 3a of the electron beam microscope 1a and through which the electron beam generated by a particle beam source passes in the longitudinal direction during operation. A first electrode 67a is provided at a side 79a of the tube 71a facing the object to be examined and the electrode is passed first by an electron coming from the object, whereupon this electron passes through a second electrode 69a and is subsequently incident on a scintillator body 57a that generates light due to the electron. Some of this light enters a light guide 59a, which guides the light to a light detector 65a that detects the light and converts the latter into electrical signals. An insulator 73a that surrounds the tube 71a and an insulator 75a that surrounds the first electrode 67a, the second electrode 69a and the scintillator 57a are provided with a certain amount of conductivity in order, in the inner and outer edge regions, to form the electric fields formed between the first electrode 67a and the second electrode 69a and the electric fields formed between the second electrode 69a and the scintillator 57a.

A ring-cylinder-shaped scintillator arrangement 76a of the first electron detector 37a is attached to an end face of the insulator 73a.

Electrons 81a incident on the scintillator body 77a of the scintillator arrangement 76a generate light in the scintillator material of the scintillator body 77a. Exemplary trajectories of such light are denoted by reference sign 83a. This light exits the scintillator arrangement 76a into the vacuum and enters a light guide 89a from the vacuum, the light guide guiding the light to a light detector 91a which detects the light and generates electrical signals that correspond to the detected light. Some of the light exiting the scintillator body 77a may enter the light guide 89a directly, i.e. without reflection off any surfaces. Another portion of the light exiting the scintillator body 77a is deflected at an optically effective surface 85a of an optical element 87a before it enters the light guide 89a. The optical element 87a is provided to increase the proportion of the light that was generated by the scintillator body 77a and enters the light guide 89a. In order to increase the proportion of the light that enters the light guide 89a and is reflected to the light detector 91a, the light guide 89a has a region 88 that tapers in wedge-shaped fashion. An angle γ between the surface of the region 88 tapering in wedge-shaped fashion that faces the object and the main axis 3a may for example range between 30°and 70°, such as between 40°and 60°.

In the case of the first electron detector 37 of the electron beam system 1 explained on the basis of FIG. 1, the optically effective surface of the optical element 87 is the mirror surface 85, which has the form of a part of an ellipsoid 99. In the case of the first electron detector 37a explained on the basis of FIG. 2, the optical element 87a of the first electron detector 37a is also a mirror, and the optically effective surface 87a is a mirror surface, off which the light generated by the scintillator body 77a is reflected and which is located in the beam path of the light between the scintillator body 77a and the light guide 89a.

In contrast to the electron beam microscope 1 explained on the basis of FIG. 1, the mirror surface 85a has the form of a part of a paraboloid. Dashed lines 99a are used in FIG. 2 to depict a continuation of the paraboloid beyond the mirror surface 85a. The paraboloid 99a is created by rotating a parabola, the axis of symmetry of which coincides with the main axis 3a of the electron beam microscope 1a. In the majority of the regions in which the mirror surface 85a exists, it is approximated to the form of the paraboloid 99a, for example by virtue of a distance between the effective mirror surface 85a and the paraboloid 99a being less than 3 mm or less than 1 mm. In a region close to the second electron detector 39a, the mirror 87a has a cutout 103a in order to allow the passage of electrons generated at the object to the scintillator body 57a of the second electron detector 39a.

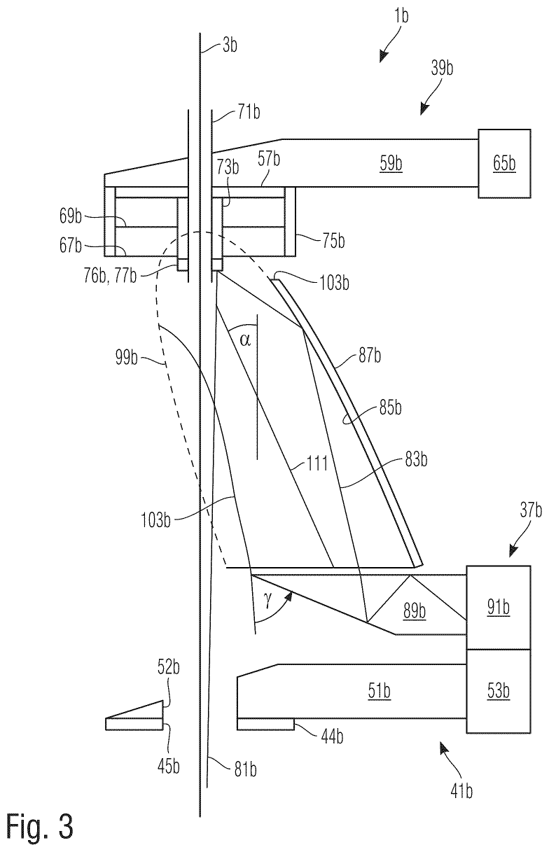

FIG. 3 is a schematic cross-sectional view of a portion of an electron beam microscope 1b according to a third embodiment. The electron beam microscope 1b shown in FIG. 3 merely differs from the electron beam microscope 1a explained on the basis of FIG. 2 in terms of the design of a first electron detector 37b. The remaining components of the electron beam microscope 1b are substantially the same as the electron beam microscope shown in FIG. 2 and are not all explained again below. Further, FIG. 3 only depicts certain components of the electron beam microscope 1b for the explanations in relation to the first electron detector 37b, and the remaining components of the electron beam microscope 1b are not depicted in FIG. 3.

A second electron detector 39b of the electron beam microscope 1b has a structure that is the same as the structure of the second electron detector of the electron beam microscopes shown in FIGS. 1 and 2. The second electron detector 39b comprises a tube 71b, which is centred with respect to a main axis 3b of the electron beam microscope 1b and through which the electron beam generated by a particle beam source passes in the longitudinal direction during operation. The second electron detector 39b also comprises a first electrode 67b, a second electrode 69b, a converter embodied as a scintillator body 57b, an insulator 73b and an insulator 75b, as were explained above in the context of the second electron detector of the electron microscopes shown in FIGS. 1 and 2.

A ring-cylinder-shaped scintillator arrangement 76b of the first electron detector 37b is attached to an end face of the insulator 73b.

Electrons incident on a scintillator body 77b of the scintillator arrangement 76b generate light in the scintillator material of the scintillator body 77b. An exemplary trajectory of such light is denoted by reference sign 83b. This light exits the scintillator arrangement 76b into the vacuum and enters a light guide 89b from the vacuum, the light guide guiding the light 83b to a light detector 91b which detects the light 83b and generates electrical signals that correspond to the detected light. Some of the light exiting the scintillator arrangement 76b may enter the light guide 89b directly, i.e. without reflection off any surfaces. Another portion of the light exiting the scintillator arrangement 76b is reflected off an optically effective surface 85b of an optical element 87b before it enters the light guide 89b. The optical element 87b is provided to increase the proportion of the light that was generated by the scintillator body 77a and enters the light guide 89b. In the case of the first electron detector 37a of the electron beam microscope 1a explained on the basis of FIG. 2, the optically effective surface 85a of the optical element 87a is a mirror surface, which has the form of a part of a paraboloid 99a. This is also the case for the first electron detector 37b. Dashed lines 99b are used in FIG. 3 to depict a continuation of the paraboloid beyond the mirror surface 85b. The paraboloid 99b is created by rotating a parabola. However, an axis of symmetry 111 of the paraboloid 99b is not coincident with the main axis 3b of the electron beam microscope 1b, as was the case for the first electron detector 37a of the electron beam microscope 1a of FIG. 2. Instead, the axis of symmetry 111 of the paraboloid makes an angle α with the main axis 3b of the electron beam microscope 1b. The angle α is the smaller of the two angles between the axis of symmetry 111 and the main axis 3b, is greater than 10°and for example is 20°.

A third electron detector 41b of the electron beam microscope 1b comprises a scintillator body 44b, a light guide 51b and a light detector 53b, as already described in the context of the third electron detector 41 of the electron beam microscope in FIG. 1. The scintillator body 44b and the light guide 51b have flush openings 45b and 52b, respectively, through which the electrons in the electron beam may pass on their path to the object and through which the electrons generated at the object may pass on their path to detection by the first electron detector 37b and the second electron detector 39b.

The light guide 89a of the first electron detector 37a also has a corresponding opening. By contrast, the light guide 89b of the first electron detector 37b does not require such an opening since all of the light reflected off the mirror surface 85b is guided on one side of the main axis 3b at such great a distance from the main axis 3b prior to entrance into the light guide 89b that such an opening is not required.

However, even in a region close to the main axis 3b, the mirror 87b has a cutout 103b in order to allow the passage of electrons generated at the object to the scintillator body 57b of the second electron detector 39b.

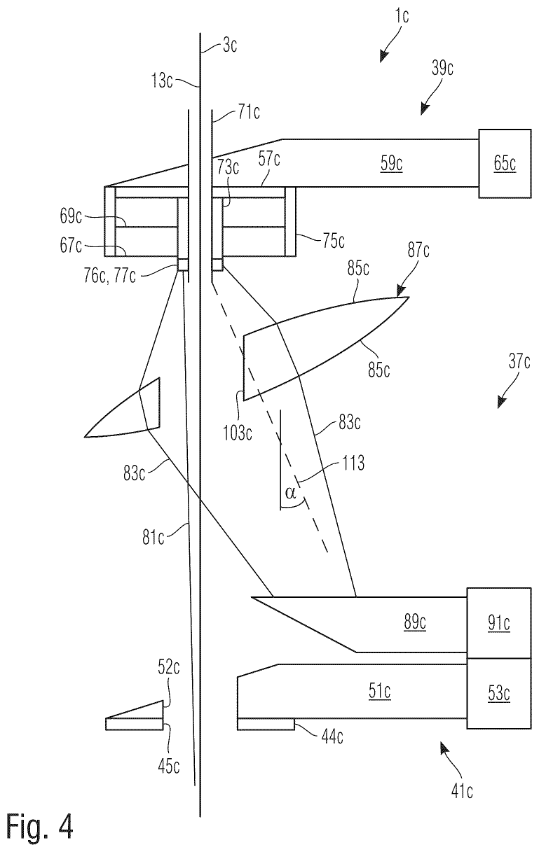

FIG. 4 is a schematic cross-sectional view of a portion of an electron beam microscope according to a fourth embodiment. The electron beam microscope 1c shown in FIG. 4 merely differs from the electron beam microscopes explained on the basis of FIGS. 1 to 3 in terms of the design of a first electron detector 37c. The remaining components of the electron beam microscope 1c are substantially the same as the electron beam microscopes shown in FIGS. 1 to 3 and are not explained again below. Further, FIG. 4 only depicts certain components of the electron beam microscope 1c for the explanations in relation to the first electron detector 37c, and the remaining components of the electron beam microscope 1c are not depicted in FIG. 4.

A second electron detector 39c of the electron beam microscope 1c has a structure that is the same as the structure of the second electron detector of the electron beam microscopes shown in FIGS. 1 to 3. The second electron detector 39c also comprises a tube 71c, which is centred with respect to a main axis 3c of the electron beam microscope 1c and through which the electron beam generated by a particle beam source passes in the longitudinal direction during operation. The second electron detector 39c also comprises a first electrode 67c, a second electrode 69c, a scintillator body 57c, an insulator 73c, an insulator 75c a light guide 59c and a light detector 65c, as were explained above in the context of the second electron detector of the electron microscopes shown in FIGS. 1 to 3.

A ring-cylindrical scintillator arrangement 76c of the first electron detector 37c is attached to an end face of the insulator 73c.

Electrons incident on the scintillator arrangement 76c generate light in a scintillator material of a scintillator body 77c of the scintillator arrangement 76c. In FIG. 4, two exemplary trajectories of such light are denoted by reference sign 83c. This light exits the scintillator arrangement 76c into the vacuum and enters a light guide 89c from the vacuum, the light guide guiding the light to a light detector 91c which detects the light and outputs electrical signals that correspond to the detected light. Some of the light exiting the scintillator arrangement 76c is deflected off an optically effective surface 85c of an optical element 87c before it enters the light guide 89c. The optical element 87c is provided to increase the proportion of the light that was generated by the scintillator body 77c and enters the light guide 89c. The optical element 87c is a lens comprising two optically effective surfaces 85c, at which the light is refracted and hence deflected in terms of its direction. The lens 87c has an optical axis 113 that extends at an angle α to the main axis 3c of the electron beam microscope 1c. For example, the angle α may be 10°. Like in the case of the electron beam microscope 1b in FIG. 3, the optical axis 113 of the lens 87c extending at an angle to the main axis 3c makes it possible that the light guide 89c of the first electron detector 37c need not have an opening in the light guide 89c.

By contrast, a light guide 51c of a third electron detector 41c has such an opening 52c. The lens 87c also provides an opening 103c in order to allow the passage of the electrons through the optical element.

In the illustrated embodiment, the lens 87c has two optically effective surfaces 85c, each of which is formed by a connected continuous surface. However, it is also possible to design one or both optically effective surfaces in such a way that they are composed of a plurality of respective continuous portions, with steps at which portions adjoin each other discontinuously being provided between adjacent portions. The plurality of portions may be provided in the style of a Fresnel lens on a shared lens body or may be provided on mutually separate lens bodies.

In the figures of the embodiments described above, the tube 71 and other components of the electron beam microscope are naturally represented schematically. For example, the geometric extents and proportions of the illustrated components do not correspond to the actual embodiments on account of the limited representation options. For example, the internal diameter of the tube 71 can be 1.0 mm to 1.5 mm, the internal diameter of the openings 45 and 52 can be for example 3 mm to 4 mm, and the internal diameter of the second end 19 of the beam tube 15 can be for example 4 mm to 5 mm.

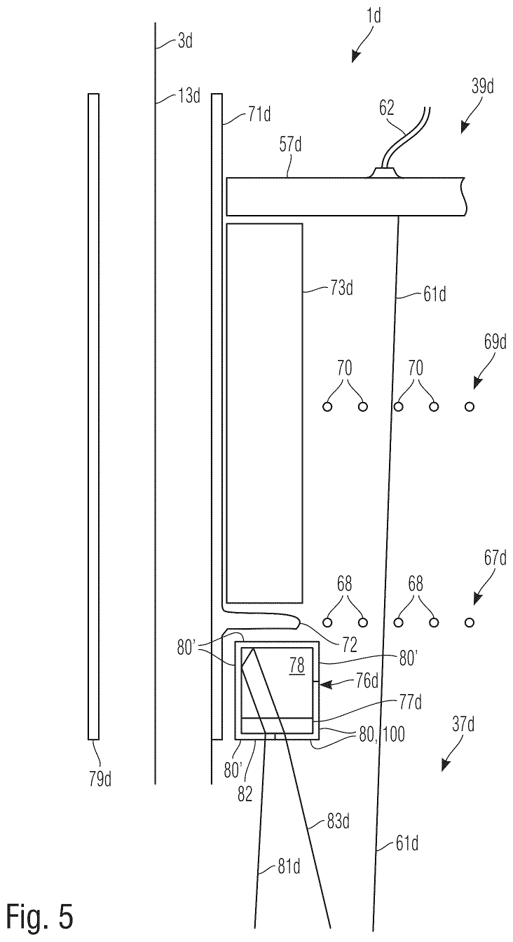

FIG. 5 is a schematic cross-sectional view of a portion of an electron beam microscope 1d according to a fifth embodiment. The electron beam microscope 1d shown in FIG. 5 merely differs from the electron beam microscope 1 explained on the basis of FIG. 1 in that a semiconductor detector 57d is provided as converter of a second electron detector 39d, the semiconductor detector using incident electrons 61d to generate electrical detection signals that are output via an electrical line 62 to a controller (not depicted in the figures) of the electron beam microscope 1d. The electrons 61d that were generated at the object by the incident electron beam 13d and are incident on the semiconductor detector 57d initially pass through a first electrode 67d, which is formed by a plurality of metal bars 68, and then pass through a second electrode 69d, which is formed by a plurality of metal bars 70. The first electrode 67d is provided on a projection 72 of a tube 71d through which the electron beam 13d passes in the longitudinal direction. Hence, the first electrode 67d is at the electric potential of the tube 71d, the electric potential of which in turn is equal to that of a beam tube 15 (not shown in FIG. 5) of the electron beam microscope 1d. The semiconductor detector 57d is also at this electric potential. The electric potential of the second electrode 69d is modifiable in order to vary the kinetic energy of the electrons 61d that the latter has as a minimum in order to reach the semiconductor detector 57d.

A scintillator arrangement 76d of a first electron detector 37d that surrounds the tube 71d as a ring cylinder is provided upstream of an object-facing end face of an insulator 73d or of the projection 72 of the tube 71d. The scintillator arrangement 76d comprises a scintillator body 77d which has an electron reception surface 82 on which the electrons 81d coming from the object are incident. By way of the incident electrons 81d, the scintillator body 77d generates light, wherein an exemplary light beam is denoted by reference sign 83d in FIG. 5. This light beam 83d passes through the scintillator body 77d and enters a light-guiding body 78 that is optically coupled to the scintillator body 77d. After two internal reflections off surfaces of the light-guiding body 78, the light beam 83d passes through the scintillator body 77d again and exits the scintillator body 77d and hence also the scintillator arrangement 76d into the vacuum, in order to be detected by a light detector (not shown in FIG. 5) of the first electron detector 37d.

The surfaces of the ring cylinder formed by the scintillator body 77d and the light-guiding body 78 are provided with two different types of coatings. A first coating 80 is provided in a radially outer region of a base surface of the ring cylinder and in an axially lower region of its outer lateral surface. This coating 80 is light-transmissive and electrically conductive. A second coating 80′is provided in the radially inner region of the base surface, the entire inner lateral surface, the entire top surface and in an upper region of the outer lateral surface. This coating 80′ is light-reflective and electrically conductive. Hence the entire ring cylinder made of the scintillator body 77d and the light-guiding body 78 is provided with the electrically conductive coatings 80 and 80′, in order to avoid local electrical charging of the surface as a result of possibly incident electrons.

The coating 80 is light-transmissive in order to allow the light to exit towards the light detector. The region of the surface of the scintillator arrangement 76d provided with the coating 80 forms a light exit surface 100 of the scintillator arrangement 76d. The coating 80′ is light-reflective in order to direct as much light as possible towards the region of the surface of the ring cylinder that is provided with the light-transmissive coating 80.

In the embodiment explained in FIG. 5, the scintillator body 77d is combined with the light-guiding body 78 in order to form a ring cylinder. However, it is also possible to form the entire ring cylinder from only one scintillator body without an additional light-guiding body being provided. Moreover, it is possible that the scintillator body 77b is very thin and for example applied to the light-guiding body 78 as a layer.

To detect the light 83d generated by the scintillator body 77d as a result of incident electrons 81d, various configurations of light detectors and optional optical elements may be provided. For example, the combinations explained on the basis of FIGS. 1, 2, 3 and 4 may be used as light detectors and optical elements for detecting the light 83b. Furthermore, the scintillator arrangement 76b explained on the basis of FIG. 5 may also be used as the scintillator arrangement of the first electron detector of the electron microscopes explained on the basis of FIGS. 1 to 4.

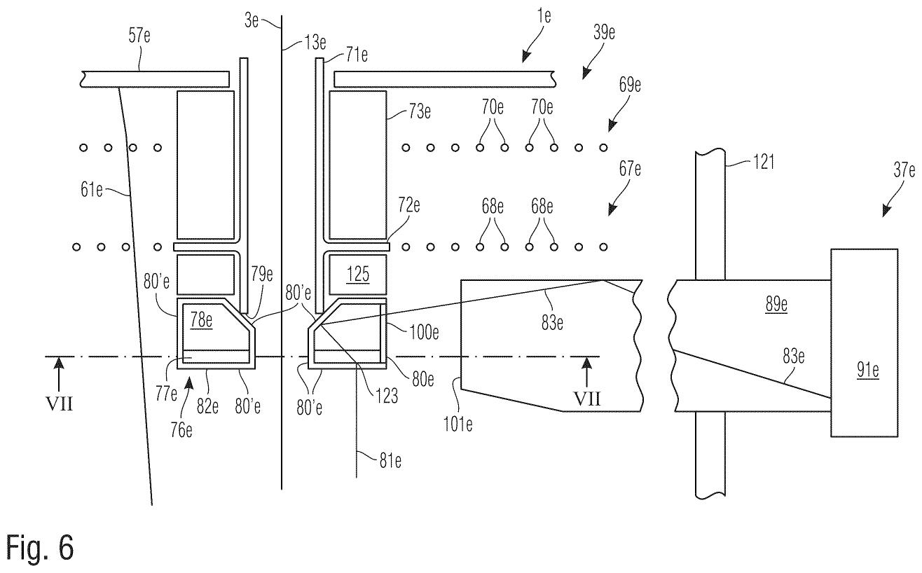

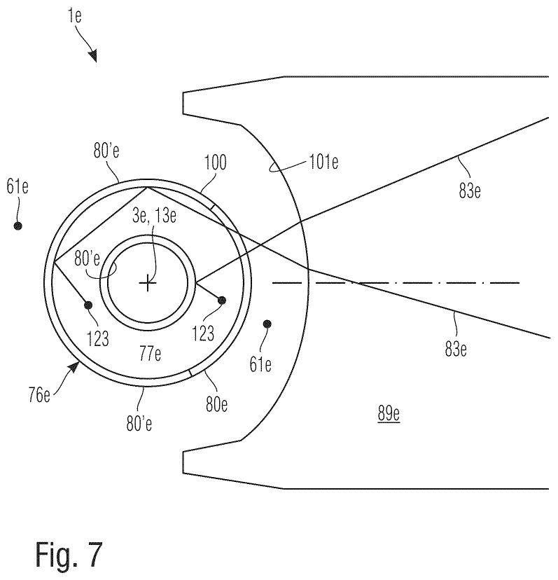

A sixth embodiment of an electron beam microscope 1e is explained below on the basis of FIGS. 6 and 7. In this context, FIG. 6 is a schematic cross-sectional view of a part of the electron beam microscope 1e, and FIG. 7 is a cross-sectional view along the line VII-VII in FIG. 6 of the part of the electron beam microscope 1e.

The electron beam microscope 1e also comprises a first electron detector 37e and a second electron detector 39e. The second electron detector 39e in turn comprises a first electrode 67e and a second electrode 69e, which an electron 61e generated at an object passes through in order to be incident on a converter 57e of the second electron detector 39e, the converter using the incident electron 61e to generate a signal, for instance a light signal or an electrical signal. To shape the electrical edge fields between the first electrode 67e and the second electrode 69e and between the second electrode 69e and the converter 57e, provision is once again made for an insulator 73e that surrounds a tube 71e through which an electron beam 13e passes in the longitudinal direction.

In the configuration according to FIG. 6, too, the second electron detector 39e has a dead area in front of the end face of the insulator 73e facing the object and in front of the end face of the tube 71e facing the object, with electrons generated at the object during the operation of the electron beam microscope being able to be incident here without being able to be detected. To detect such electrons, a scintillator arrangement 76e, by means of which electrons 81e coming from the object are converted into light that can be detected by a light detector 91e of the first electron detector 37e, is arranged on an end 79e of the tube 71e facing the object. The scintillator arrangement 76e has the form of a ring cylinder, which is assembled from a scintillator body 77e and a light-guiding body 78e and provided with coatings 80e and 80′e. The coating 80e is electrically conductive and light-transmissive, while the coating 80′e is electrically conductive and light-reflective.

The plane VII-VII in FIG. 6 extends orthogonal to a main axis 3e of the electron beam microscope 1e and passes through the scintillator body 77e. It is evident from the cross-sectional view of FIG. 7 that the electron beam 13e passes through the plane VII-VII in a centre of the scintillator arrangement 76e which coincides with the main axis 3e. The scintillator body 77e at least partially surrounds the centre 3e and surrounds this in full in the exemplary embodiment of FIGS. 6 and 7 since the scintillator body forms a complete ring around the main axis 3e. However, it is also possible that the scintillator body only partially surrounds the main axis 3e or that a plurality of scintillator bodies are provided, which as segments each surround the main axis 3e only in part.

Further, in the plane VII-VII, the scintillator body 77e is arranged between the centre 3e and a region of the plane VII-VII that is traversed by the electrons that are detected by the second electron detector 39e. A point denoted by reference sign 61e in FIG. 7 represents an electron that is detected by the second electron detector 39e and passes through the plane VII-VII outside of the scintillator body 77e.

The description of the conditions in the plane VII-VII on the basis of FIG. 7, provided up until this point, also holds true for the embodiments of FIGS. 1, 2, 3, 4 and 5 since a scintillator body is also formed there as a ring that at least partially surrounds the main axis of the electron microscope or the centre, and the ring is arranged between the centre and the region of the plane traversed by electrons generated at the object that are detected by the second electron detector.

While the above-described embodiments use an optical element, such as a mirror in the embodiments of FIGS. 1, 2 and 3 or a lens in the embodiment of FIG. 4, to increase the component of the light that is generated by the scintillator body and reaches the light detector of the first electron detector, the embodiment of FIGS. 6 and 7 does not provide such an optical element, and the light 83e exiting the scintillator arrangement 76e into the vacuum directly enters a light guide 89e of the first electron detector 37e. To this end, the scintillator arrangement 76e comprises a light exit surface 100e, through which the light 83e exits the scintillator arrangement 76e, and the light guide 89e comprises a light entrance surface 101e, through which the light 83e enters the light guide 89e. The light guide 89e serves to guide the light 83e that enters it to the light detector 91e. FIG. 6 depicts a vacuum cladding 121 through which the light guide 89e passes such that the light detector 91e may be arranged outside of a vacuum chamber of the electron beam microscope 1e.

Among the surfaces of the scintillator arrangement 76e, a part facing the light entrance surface 101e of the light guide 89e is formed as the light exit surface 100e by virtue of the surface of the scintillator arrangement 76e there being provided with the electrically conductive and light-transmissive coating 80e. All remaining surfaces of the scintillator arrangement 76e are provided with the electrically conductive and light-reflective coating 80′e. Points denoted by reference sign 123 in FIG. 7 represent locations at which light is generated in the scintillator body 77e, and lines 83e emanating from the points 123 by way of example represent light that is reflected off surfaces provided with the reflective coating 80′e and exits the scintillator arrangement 76e at the light exit surface 100e, which is provided with the light-transmissive coating 80e, in order to enter the light guide 89e. The light entrance surface 101e of the light guide 89e is arranged at a distance from the light exit surface 100e of the scintillator arrangement such that electrons 61e that are generated at the object and detected by the second electron detector 39e are able to pass through the plane VII-VII even in the region between the light entrance surface 101e of the light guide 89e and the light exit surface 100 of the scintillator arrangement 76e.

It is also evident from the sectional illustration of FIG. 7 that the light entrance surface 101e has a concave embodiment in order to reduce the component of the light reflected off the light entrance surface 101e and in order to refract the light entering the light guide 89e towards the light detector.

From the sectional illustration in FIG. 6 of the plane containing the main axis 3e or the electron beam 13e, it is further possible to gather that the light exit surface 100e of the scintillator arrangement 76e extends substantially parallel to the main axis 3e, and the electron reception surface of the scintillator body 76e extends substantially orthogonal to the main axis 3e. Further, in the sectional illustration of FIG. 6, the light entrance surface 101e of the light guide 89e also extends substantially parallel to the main axis 3e. However, it is also possible to design the light entrance surface 101e in such a way that it extends not in a straight line but concavely in order to reduce the component of the light reflected off the light entrance surface 101e and refract the entering light towards the light detector 91e.

In the direction of the main axis 3e, the light guide 89e has a greater extent than the light exit surface 100e, whereby the component of the light exiting the scintillator arrangement 76e and entering the light guide 89e can be increased. The light guide 89e partially extends in the vicinity of the second electrode 67e of the second electron detector 39e, whereby the second electrode 67e provides an upward restriction to the position of the light guide 89e in the illustration of FIG. 6. In order to arrange the light exit surface 100e of the scintillator arrangement 76e approximately centrally opposite to the light entrance surface 101e of the light guide 89e, a spacer 125 that surrounds the tube 71e like the insulator 73e is provided between the first electrode 67e of the second electron detector 39e and the scintillator arrangement 76e of the first electron detector 37e. On account of the spacer 125, the scintillator arrangement 76e is arranged at a greater distance from the first electrode 67e of the second electron detector 39e than the one based on FIGS. 1 to 5.

In the embodiments explained on the basis of FIGS. 1 to 5, the tube 71 passes through the scintillator arrangement 76 or the scintillator arrangement 76 surrounds the lower end 79 of the tube 71.

In the embodiment of FIGS. 6 and 7, an internal diameter of the ring-cylindrical scintillator arrangement 76e is slightly smaller than an internal diameter of the tube 71e such that electrons that in the embodiments of FIGS. 1 to 5 would be incident on the end face of the tube 71 facing the object can also be incident on the electron reception surface 82e of the scintillator arrangement 76e and be detected.

It is evident from the sectional view of FIG. 6 that the cross-sectional form of the ring-cylindrical scintillator arrangement 76e is not quite quadrilateral but pentagonal in such a way that an inclined surface is provided at the top and the inside of the ring-cylindrical form, the surface normal of the surface extending at approximately 45° to a surface normal of the electron reception surface 82e. This surface that extends obliquely in the sectional illustration of FIG. 6 and extends conically on the ring-cylinder form of the scintillator arrangement 76e serves to increase the component of the light generated in the scintillator body 77e that is reflected towards the light guide 89e.

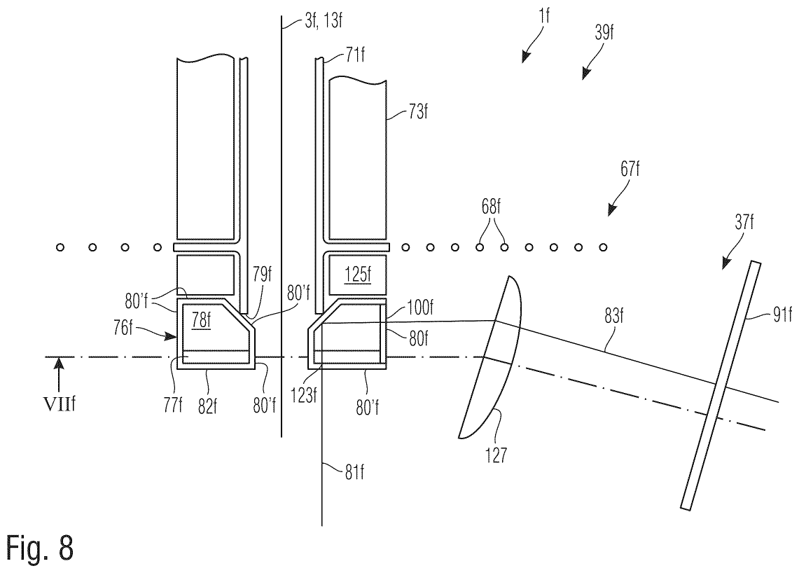

FIG. 8 is a schematic cross-sectional view of a portion of an electron beam microscope according to a seventh embodiment. The electron beam microscope 1f of FIG. 8 differs from the electron beam microscope 1e that was explained on the basis of FIGS. 6 and 7 in that light 83f exiting a scintillator arrangement 76f of a first electron detector 37f is not guided to a light detector 91f of the first electron detector 37f by a light guide (89b in FIG. 6), instead a lens 127 with positive refractive power is provided in a beam path of the light 83f between the scintillator arrangement 76f and the light detector 91f in order to increase the component of the light reaching the light detector 91f.

Otherwise, the electron beam microscope 1f also comprises a first electron detector 37f and a second electron detector 39f. The second electron detector 39f is configured to select the kinetic energy of the electrons that are generated at the object and ultimately detected, for the purpose of which these electrons pass through a first electrode 67f and a second electrode (not depicted in FIG. 8), to which a variable electric potential can be applied. The scintillator arrangement 76f of the first electron detector 37f is arranged in front of an insulator 73f and a tube 71f of the second electron detector 39f through which the electron beam 13f passes. The scintillator arrangement 76f once again has a ring-cylindrical form, the surfaces of which are coated with coatings 80f and 80′f. The coatings 80f and 80′f in the scintillator arrangement have a similar design to those in the scintillator arrangement explained on the basis of FIGS. 6 and 7, in which a light exit surface 100f provided with the electrically conductive and light-transmissive coating 80f is formed on a side of the scintillator arrangement 76f facing the lens 127, while all remaining parts of the surface of the scintillator arrangement 76f are provided with the electrically conductive and light-reflective coating 80′f. The light 83f exiting the light exit surface 100f of the scintillator arrangement 76f divergently is collimated by the lens 127 and directed at the light detector 91f.

In the first electron detector 37f of the seventh embodiment, the lens 127 is used to increase the component of the light 83f exiting the scintillator arrangement 76f that reaches the light detector 91f. The lens 87c is also used for this purpose in the exemplary embodiment explained on the basis of FIG. 4. However, in the exemplary embodiment of FIG. 4, the electron reception surface of the scintillator arrangement is used as the light exit surface such that the light 83c exiting from the scintillator arrangement is directed substantially downwardly, towards the object, which is why the lens 87c is also arranged along the beam path of the electron beam 13c between the scintillator arrangement 76c and the object. In the exemplary embodiment of FIG. 8, by contrast, the electron reception surface 82f of the scintillator arrangement 76f is provided with the light-reflective coating 80′e, and only a portion of the side face of the scintillator arrangement 76f is used as the light exit surface 100f, and so the light 83f is emitted divergently out of the scintillator arrangement 76f, in a manner substantially perpendicular to the main axis 3f. In order to allow the lens 127 that is larger in comparison with the extent of the scintillator arrangement 76f to be arranged in the vicinity of the first electrode 67f, a spacer 125f is once again arranged between the first electrode 67f and the scintillator arrangement 76f.

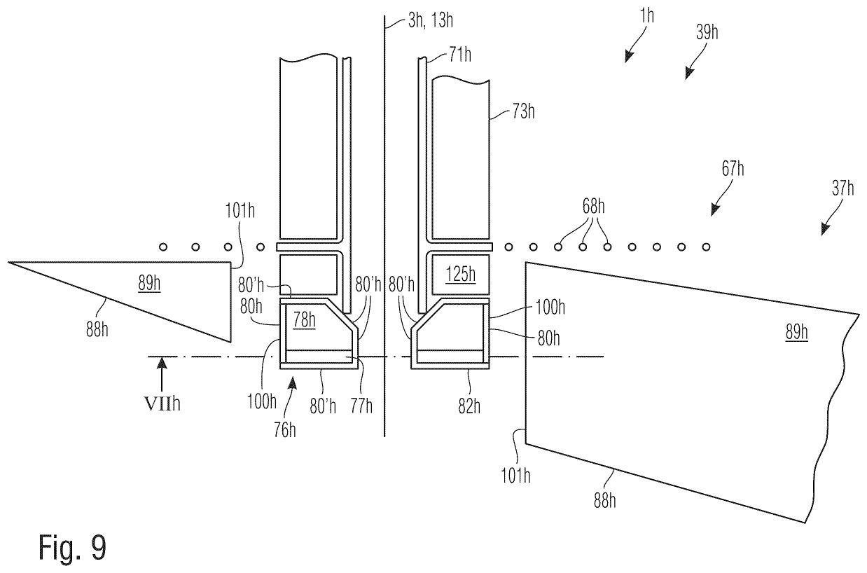

FIG. 9 is a schematic cross-sectional view of a portion of an electron beam microscope 1h according to an eighth embodiment. The electron beam microscope 1h has a similar structure to the electron beam microscope 1e explained on the basis of FIGS. 6 and 7. It differs from the latter substantially in terms of the configuration of a light entrance surface 101h of a light guide 89h of a first electron detector 37h and in terms of the configuration of a light exit surface 100h of a scintillator arrangement 76h of the first electron detector 37h. While the light entrance face 101e of the light guide 89e of the first electron detector 37e of the electron beam microscope 1e of FIGS. 6 and 7 surrounds the scintillator arrangement 76e merely in part on one side (the right-hand side in FIGS. 6 and 7), the light entrance surface 101h of the light guide 89h surrounds the scintillator arrangement 76h completely, as seen in a plane VIIh that is orthogonal to the beam path of an electron beam 13h and intersects a scintillator body 77h of the scintillator arrangement 76h. Projected onto the plane VIIh, the electron receiver surface 82h has the form of an annulus that is centred with respect to the main axis 3h. Moreover, the light guide 89h has a region 88h that tapers like a wedge in order to orient light entering the light guide 89h through the light entrance surface 101h towards an end of the light guide 89h that is opposite the region 88h by reflection, where a light detector of the first electron detector 37h (not depicted in FIG. 9) is arranged, as already explained on the basis of FIG. 2.

Of the various surfaces of the scintillator arrangement 76h, the entire outer lateral surface of the ring-cylindrical body is provided with an electrically conductive light-transmissive coating 80h in order to form the light exit surface 100h. All remaining surfaces of the scintillator arrangement 76h are provided with an electrically conductive and light-reflective coating 80′h.

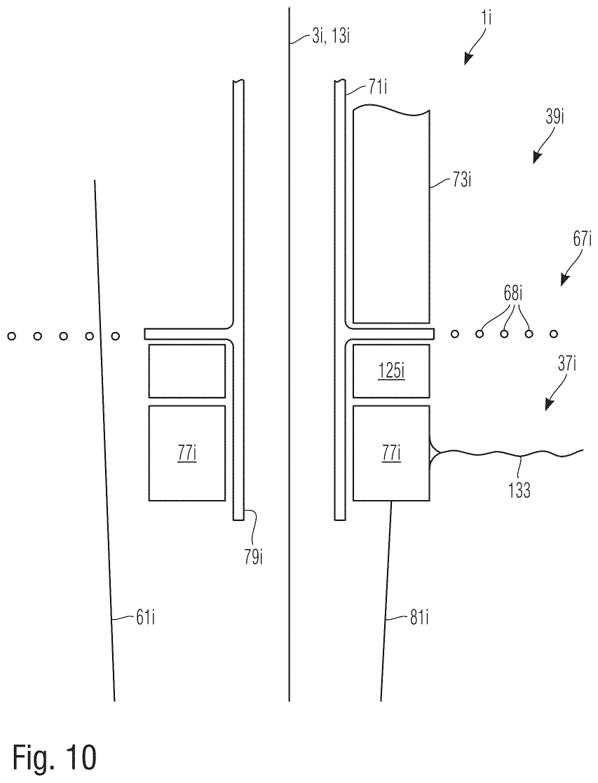

FIG. 10 is a schematic cross-sectional view of a part of an electron beam microscope 1i that has a similar structure as the electron beam microscopes explained above on the basis of FIGS. 1 to 9 by virtue of having a first electron detector 37i and a second electron detector 39i. The second electron detector 39i is configured to select the kinetic energy of the electrons that are generated at the object and ultimately detected, for the purpose of which these electrons pass through a first electrode 67i and a second electrode (not depicted in FIG. 10), to which a variable electric potential can be applied.

However, in contrast to the previous electron beam microscopes explained on the basis of FIGS. 1 to 9, the first electron detector 37i does not comprise any scintillator body as a converter for converting electrons 81i coming from the object into light. Instead, the first electron detector 37i comprises a semiconductor detector 77i as a converter for generating electrical signals as a consequence of a detection event triggered in the semiconductor detector 77i by the incidence of an electron 81i. The electrical signals generated are guided away from the semiconductor detector 77i by way of an electrical line 133 and are supplied to a controller of the electron microscope 1i (not depicted in the figure).

From the view of the object, the semiconductor detector 77i is arranged in front of an annular end face of an insulator 73i of the second electron detector 39i in order to detect the electrons 81i that would not be detectable without the presence of the semiconductor detector 77i.

A ring-shaped spacer 175i (which may be omitted) is arranged between the semiconductor detector 77i and the first electrode 67i of the second electron detector 39i such that the semiconductor detector 77i is arranged closer to the first electrode 67i.

1. An electron beam microscope, comprising:
an electron beam source configured to generate an electron beam;
an objective lens along a beam path of the electron beam between the electron beam source and a location of an object, the objective lens configured to focus the electron beam on the location of the object; and
a first electron detector configured to detect electrons generated at the object by the electron beam;
wherein the first electron detector comprises:
a scintillator arrangement along the beam path of the electron beam between the electron beam source and the object location so that the electrons generated at the object are incident on a scintillator body of the scintillator arrangement, the scintillator body comprising a scintillator material configured to generate light from incident electrons;
a light detector configured to detect light generated by the scintillator body and to convert the light into electrical signals; and
an optical element comprising an optically effective surface along the beam path of the electron beam between the scintillator arrangement and the object location, the optical element between the scintillator body and the light detector in a beam path of the light detected by the light detector.

2. The electron beam microscope of claim 1, wherein the light detector is along the beam path of the electron beam between the scintillator arrangement and the location of the object.

3. The electron beam microscope of claim 1, wherein the scintillator arrangement comprises a light exit surface through which the light generated by the scintillator material exits the scintillator arrangement, and wherein the light detector is along the beam path of the electron beam between the light exit surface of the scintillator arrangement and the location of the object.

4. The electron beam microscope of claim 1, wherein the scintillator arrangement comprises a light exit surface through which the light generated by the scintillator material exits the scintillator arrangement, wherein the electron beam microscope furthermore comprises a light guide comprising a light entrance surface through which the light exiting the light exit surface of the scintillator arrangement enters the light guide, wherein the light guide is configured to guide light entering the light guide through the light entrance surface to the light detector, and wherein the light entrance surface of the light guide is along the beam path of the electron beam between the light exit surface of the scintillator arrangement and the location of the object.

5. The electron beam microscope of claim 1, wherein the optical element comprises a mirror, and the optically effective surface comprises a mirror surface configured to reflect the light detected by the light detector.

6. The electron beam microscope of claim 5, wherein the mirror surface comprises a curved surface.

7. The electron beam microscope of claim 6, wherein an ellipsoid is fittable to the mirror surface so that a greatest distance between the mirror surface and the ellipsoid is less than 3 millimeters (mm).

8. The electron beam microscope of claim 7, wherein a distance between a focus of the ellipsoid and the scintillator body is less than 5 mm.

9. The electron beam microscope of claim 6, wherein a paraboloid is fittable to the mirror surface so that a greatest distance between the mirror surface and the paraboloid is less than 3 millimeters.

10. The electron beam microscope of claim 1, wherein the optical element comprises a lens, and the optically effective surface comprises a surface of the lens configured to refract the light detected by the light detector.

11. The electron beam microscope of claim 10, wherein the surface comprises an electrically conductive layer that is transmissive to the light generated by the scintillator body.

12. The electron beam microscope of claim 1, wherein the lens has an optical axis making a smallest angle of greater than 4° with the beam path of the electron beam.

13. The electron beam microscope of claim 1, wherein the optically effective surface has an area of greater than 10 mm².

14. The electron beam microscope of claim 1, wherein the optical element comprises a cutout through which the beam path of the electron beam extends.

15. The electron beam microscope of claim 1, wherein the first electron detector comprises a light guide between the optically effective surface and the light detector in the beam path of the light detected by the light detector.

16. The electron beam microscope of claim 1, wherein the scintillator arrangement comprises an electron reception surface at which the electrons generated at the object are incident on the scintillator body, wherein the scintillator arrangement comprises a light exit surface through which the light generated by the scintillator material exits the scintillator arrangement, and wherein the electron reception surface and the light exit surface at least partially overlap.

17. The electron beam microscope of claim 1, further comprising a second electron detector comprising a converter, a first electrode, a second electrode, a tube and an insulator,
wherein the beam path of the electron beam passes through the tube in the longitudinal direction of the latter,
wherein each of the converter, the first electrode and the second electrode is arranged outside of the tube and spaced from the others along the beam path of the electron beam,
wherein the converter is along the beam path of the electron beam between the electron beam source and the first electrode so that electrons generated at the object pass through the first electrode and are incident on the converter,
wherein the converter is configured to convert the electrons generated at the object into electrical or optical signals,
wherein the second electrode is along the beam path of the electron beam between the first electrode and the converter,
wherein the electrons generated at the object pass through the second electrode after passing through the first electrode,
wherein the tube has an electrically conductive inner lateral surface,
wherein the insulator comprises an electrically insulating material,
wherein the insulator surrounds the tube along the beam path of the electron beam at least in a region between the first electrode and the second electrode and in a region between the second electrode and the converter, and
wherein the scintillator body of the first electron detector is along the beam path of the electron beam between the first electrode and the location of the object or between the second electrode and the location of the object and, in the direction of the beam path, at least partially overlaps with the insulator.

18. An electron beam microscope, comprising:
an electron beam source configured to generate an electron beam;
an object holder configured to mount the object at the location of object;
an objective lens along a beam path of the electron beam between the electron beam source and the location of the object and configured to focus the electron beam on the location of the object;
a first electron detector configured to detect electrons generated at the object by the electron beam; and
a second electron detector configured to detect electrons generated at the object by the electron beam,
wherein the second electron detector comprises a converter, a first electrode, a second electrode, a tube and an insulator,
wherein the beam path of the electron beam passes through the tube in a longitudinal direction of the tube,
wherein each of the converter of the second electron detector, the first electrode and the second electrode is arranged outside of the tube and spaced from the others along the beam path of the electron beam,
wherein the converter of the second electron detector is along the beam path of the electron beam between the electron beam source and the first electrode so that electrons generated at the object pass through the first electrode and are incident on the converter,
wherein the converter of the second electron detector is configured to convert the electrons generated at the object into electrical or optical signals;
wherein the second electrode is along the beam path of the electron beam between the first electrode and the converter of the second electron detector,
wherein the electrons generated at the object pass through the second electrode after passing through the first electrode,
wherein the tube comprises an electrically conductive inner lateral surface;
wherein the insulator comprises an electrically insulating material;
wherein the insulator surrounds the tube along the beam path of the electron beam and at least in a region between the first electrode and the second electrode and in a region between the second electrode and the converter,
wherein the first electron detector comprises a converter configured to convert electrons generated at the object into electrical or optical signals, and
wherein the converter of the first electron detector is along the beam path of the electron beam between the second electrode and the location of the object or between the first electrode and the location of the object and, as seen in the direction of the beam path, at least partially overlaps with the insulator.

19. The electron beam microscope of claim 17, wherein the tube carries the converter of the first electron detector.

20.-26. (canceled)

27. An electron beam microscope, comprising:
an electron beam source configured to generate an electron beam;
an object holder configured to mount an object at an location of the object on which the electron beam is incident;
an objective lens arranged along the beam path of the electron beam between the electron beam source and the location of the object and configured to focus the electron beam on the location of the object;
a first electron detector configured to detect electrons generated at the object by the electron beam; and
a second electron detector configured to detect electrons generated at the object by the electron beam;,
wherein the second electron detector comprises a converter configured to convert electrons generated at the object and incident on an electron reception surface of the converter into electrical or optical signals,
wherein the first electron detector comprises a converter configured to convert electrons generated at the object and incident on an electron reception surface of the converter into light,
wherein the converter of the first electron detector comprises a scintillator body providing the electron reception surface of the converter and comprising a scintillator material that generates the light from the electrons generated at the object and incident on the scintillator body, and
wherein the following holds in a plane orthogonal to the beam path of the electron beam and intersecting the scintillator body:
during operation the electron beam passes through the plane at a centre;
the scintillator body at least partially surrounds the centre; and
the scintillator body is between the centre and a region of the plane traversed by the electrons generated at the object by the electron beam and incident on the electron reception surface of the second electron detector.

28.-39. (canceled)
